(19) United States
(12) Patent Application Publication
(10) Pub. No.: US 2008/0225494 A1
(43) Pub. Date: Sep. 18, 2008

(54) SOLID-STATE HARD DISK DRIVE

(76) Inventor: Chih-Yi YANG, Taipei (TW)

Correspondence Address: HDSL, 4331 STEVENS BATTLE LANE, FAIRFAX, VA, 22033, US

(21) Appl. No.: 11/685,232

(22) Filed: Mar. 13, 2007

(51) Int. Cl. H05K 7/16

(52) U.S. Cl. 361/727

(57) ABSTRACT

A solid-state hard disk drive, taking solid-state memory as storage media, is assembled by magnetic disk array configuration, mainly including a device body and a plurality of solid-state memories, wherein the left and right of the device body respectively have a plurality of inserting grooves for accommodating and arranging the solid-state memories, the bottom part of each inserting groove separately having a connecting seat for connecting the solid-state memory, wherein the bottom part of the device body is arranged a connecting interface, furthermore, a control unit being arranged at the interior of the device body and being electrically connected to each connecting seat and connecting interface respectively, and thus an integral memory with capacity accumulation is integrated by the connecting seat that controls each solid-state memory, finally a single hard disk drive being simulated.

### BACKGROUND OF THE INVENTION

1. Field of the Invention

The present invention in general relates to a magnetic disk array, in particular, to a magnetic disk array assembled by solid-state memory.

2. Description of Prior Art

Since server has been used in large quantity with the conditions of security, large capacity, and high-speed accession required by current information storage, magnetic disk array system thereby becomes an optimal choice in recent middle and low level storage facilities, owing to the prevalence of the web application environment. At present market, almost all magnetic disk array systems are assembled according to the RAID (Redundant Arrays of Inexpensive Disks) specification defined by RAID Advisory Board. Different RAID level has its different application environment. However, in general speaking, magnetic disk array system is to provide a storage facility with large capacity and high effectiveness, thus the appropriateness of data being able to be enhanced.

However, in the current application where the real body of hard disk in magnetic disk array configuration is a mechanical hard disk structure, a reading needle head is reciprocated in a linear motion simultaneously in cooperation with the rotation of the magnetic disk, such that the reading needle head may process the writing or reading motion in different magnetic zones on the magnetic disk but, regarding to accessing appropriateness, such mechanical hard disk structure must depend upon the inter-cooperation between the reading needle head and the magnetic disk, so it takes a lot of time in the accessing procedure consequently, making specific limitation and bottleneck existed in the reading time and the speed of such mechanical hard disk. In terms of current hard disk technology, in order to enhance the accessing speed of hard disk, although the rotating speed of magnetic disk is promoted for compensating the inherent limitation on accessing speed, the problem of high heat is still occurred by accelerating the rotating speed of the magnetic disk during the promotion of the rotation speed of the magnetic disk, making it become a largest heating source in the system. Furthermore, after the data accessing speed of the current magnetic disk is increased significantly, the anti-seismic ability of the magnetic disk is lowered down relatively. In addition, besides the high heat problem in this mechanical hard disk itself, it is also easy to make the rotating magnetic disk generate coagulating state to influence the rotating speed even to cause the device shut down under the operating condition of lower temperature, relatively lowering down the accessing speed of the hard disk, so there are still lots of problems existed in the traditional mechanical hard disk under the adverse circumstance of poor heat dissipation, low temperature and high vibration.

Therefore, besides accelerating the accessing speed of hard disk drive, in order to overcome the adverse environment, the prior arts propose a solid-state hard disk drive structure, which adopts a magnetic disk array configuration composed of a plurality of solid-state memories to simulate a single hard disk drive. Besides the accessing manner of the solid-state memory being different from that of the mechanical hard disk, which may highly be adapted to the adverse circumstance of high vibration, while its operating temperature range is very extensive, the solid-state memory has the characteristic of high accessing speed that is sufficiently fulfilled the requirement of data storage, so this kind of solid-state hard disk drive indeed has a significant competitiveness.

However, in traditional mechanical hard disk drive or current solid-state hard disk drive taking solid-state memory as storage media, they commonly lack the design function of extension and exchange. In the meanwhile, the solid-state memory has a specific accessing lifetime so, when the solid-state memory is damaged or the memory capacity is insufficient, the only one way to deal with it is to change the entire hard disk drive, making an insufficiency in an otherwise perfect design.

### SUMMARY OF THE INVENTION

Regarding to aforementioned drawbacks, the main objective of the present invention is to provide a solid-state hard disk drive simultaneously capable of extending the capacity and exchanging the solid-state memory by arranging a hard disk drive of institutional standard with a plurality of inserting grooves for accommodating plural solid-state memories so, not only the capacity of the hard disk drive may be promoted by the increasing number of the inserting groove, but also the solid-state memory may be renewed for maintaining a normal operation of the hard disk drive when the solid-state memory is damaged or the memory capacity is full.

To achieve above objectives, the invention provides a solid-state hard disk drive that takes solid-state memory as storage media and is assembled by magnetic disk array configuration, mainly including a device body and a plurality of solid-state memories, wherein the left and right of the device body respectively have a plurality of inserting grooves for accommodating and arranging the solid-state memories, the bottom part of each inserting groove separately having a connecting seat for connecting the solid-state memory, wherein the bottom part of the device body is arranged a connecting interface, furthermore, a control unit being arranged at the interior of the device body and being electrically connected to each connecting seat and connecting interface respectively, and thus an integral memory with capacity accumulation is integrated by the connecting seat that controls each solid-state memory.

### BRIEF DESCRIPTION OF DRAWING

The features of the invention believed to be novel are set forth with particularity in the appended claims. The invention itself, however, may be best understood by reference to the following detailed description of the invention, which describes exemplary embodiments of the invention, taken in conjunction with the accompanying drawings, in which:

FIG. 1 is a perspective structure view according to one embodiment of the present invention;

FIG. 2 is a block illustration according to one embodiment of the present invention;

FIG. 3 is a connecting illustration according to one embodiment of the present invention;

FIG. 4 is a rear view of the device body of the present invention;

FIG. 5 is a perspective structure view according to another embodiment of the present invention;

FIG. 6 is a block illustration according to another embodiment of the present invention; and

FIG. 7 is a connecting illustration according to another embodiment of the present invention.

### DETAILED DESCRIPTION OF THE INVENTION

In cooperation with attached drawings, the technical contents and detailed description of the present invention will be as follows. However, the attached figures are only for the purpose of reference and description, not for limiting the scope of the present invention.

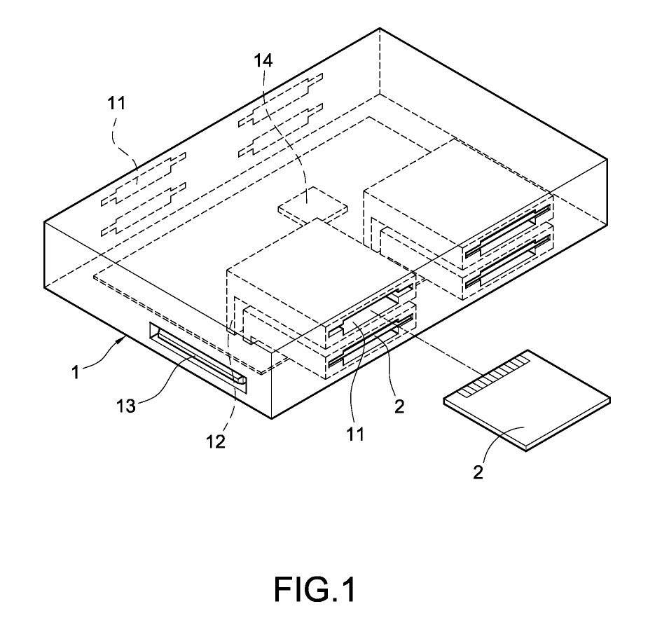

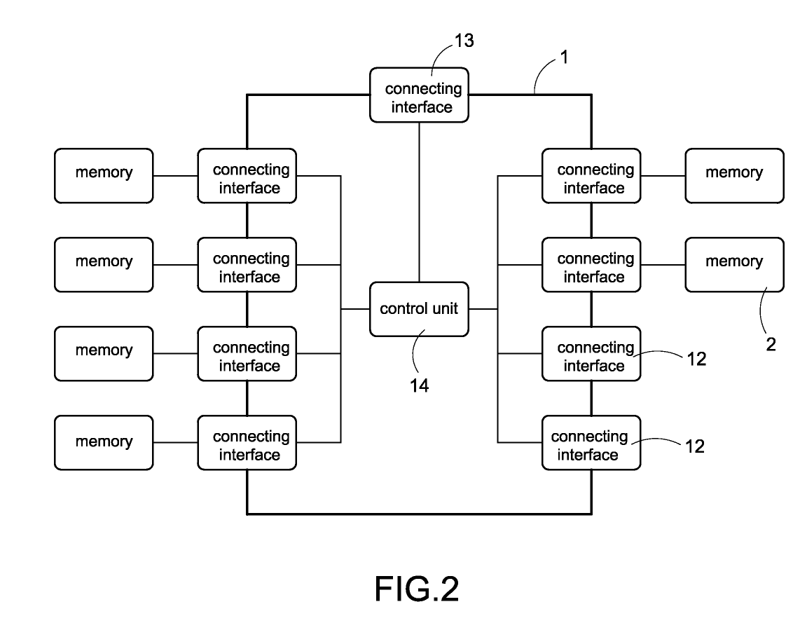

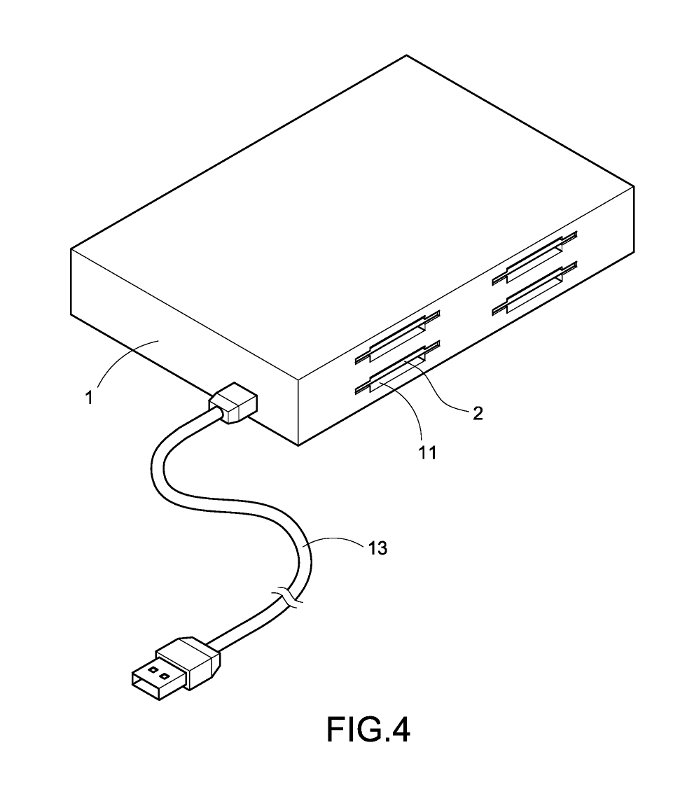

Please refer to FIG. 1 and FIG. 2, which respectively are a perspective structure view and a block illustration according to one embodiment of the present invention. As shown in these figures, the hard disk drive of the present invention is assembled by a magnetic disk array (RAID) configuration, mainly including: a device body 1 and a plurality of solid-state memories 2, wherein the size of the device body 1 may be the specification of 3.5 inch hard disk box or 5.25 inch hard disk box. The specification of 3.5 inch hard disk box is described in this embodiment. Wherein, the left and right sides of the device body 1 are respectively arranged a plurality of inserting grooves 11 with same accommodating specification. The inserting groove 11 is adapted to accommodate the solid-state memory 2 in a manner, such that the storage capacity of the hard disk drive may be changed according to the quantity of the inserting groove 11. In the meanwhile, the bottom part of the inserting groove 11 is arranged a connecting seat 12 for being electrically connected to the solid-state memory 2. Furthermore, the bottom part of the device body 1 is arranged a connecting interface 13, which is adapted for being connected to the computer mainframe. In the present invention, the connecting seat 12 and connecting interface 13 may be a sequential ATA (SATA) or a parallel ATA (IDE). In addition, the connecting interface 13 may also be a USB connector as shown in FIG. 4; the interior of the device body 1 is arranged a control unit 14, which is electrically and respectively connected to the connecting seat 12 at the bottom part of each inserting groove 11 and the connecting interface 13, and which is embedded with control software, such that the control unit 14 may be electrically connected to the solid-state memories 2 through each connecting seat 12, making plural solid-state memories 2 connected integrally, whereby the capacities of plural solid-state memories 2 are accumulated to simulate a single hard disk drive. As shown in the configuration diagram of FIG. 2, the solid-state memory 2 is a solid-state memory of non-volatility, for example a flash memory, taken as one real memory body of the accumulated capacity under the configuration of a magnetic disk array (RAID). Through the design of the inserting groove 11 and the connecting seat 12 on the device body 1, the solid-state memory 2 possesses the switching function. The solid-state memory 2 may renewed at any time, when the capacity of specific solid-state memory 2 is full or certain solid-state memory 2 is damaged.

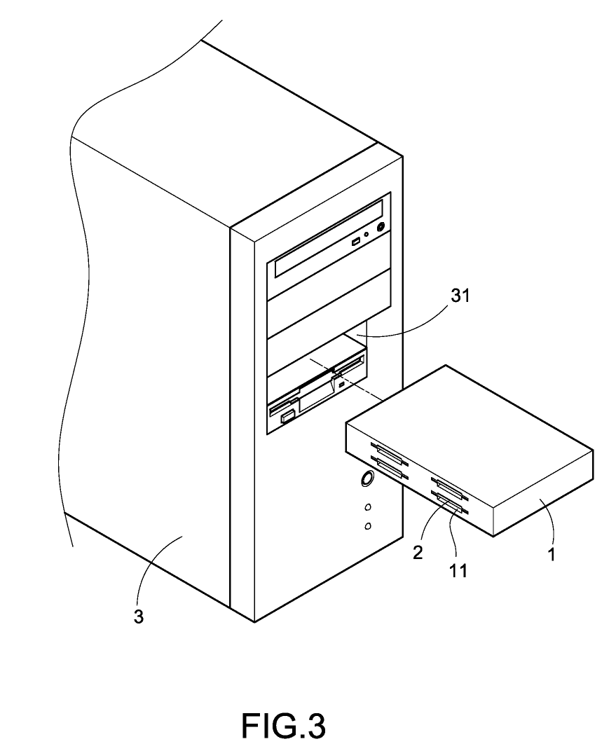

Please refer to FIG. 3, which is an operational illustration of the present invention. Thereby, when the hard disk of the present invention is arranged in the hard disk accommodating space 31 of a computer mainframe 3, the connecting interface 13 on the device body 1 is electrically connected to the computer mainframe 3, taken as an information-transmitting path. When the order or data to be retrieved is received by the control unit 14 through the connecting interface 13, the order or data is re-integrated by the internal software set in the control unit 14, and the order or data is then stored in each solid-state memory 2. As soon as the connected solid-state memory 2 is full or damaged, it may be changed at any time.

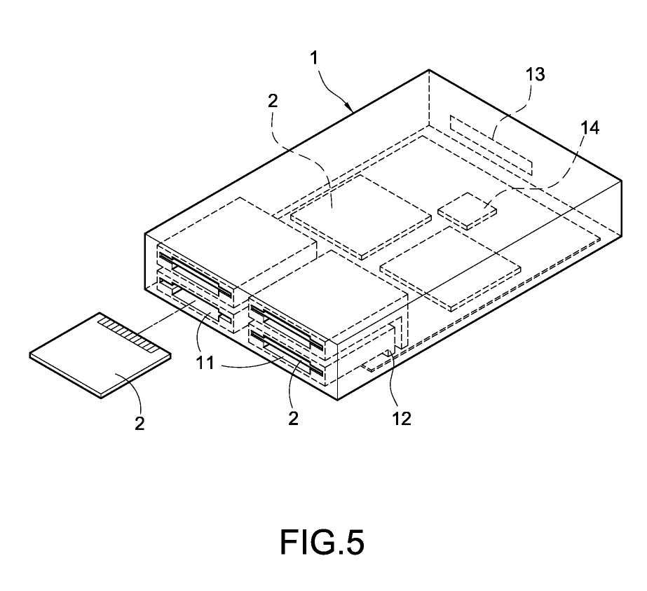

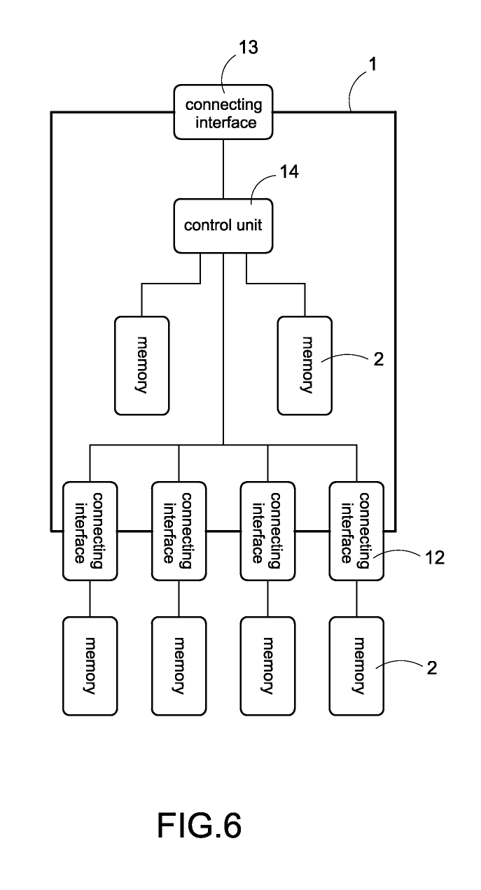

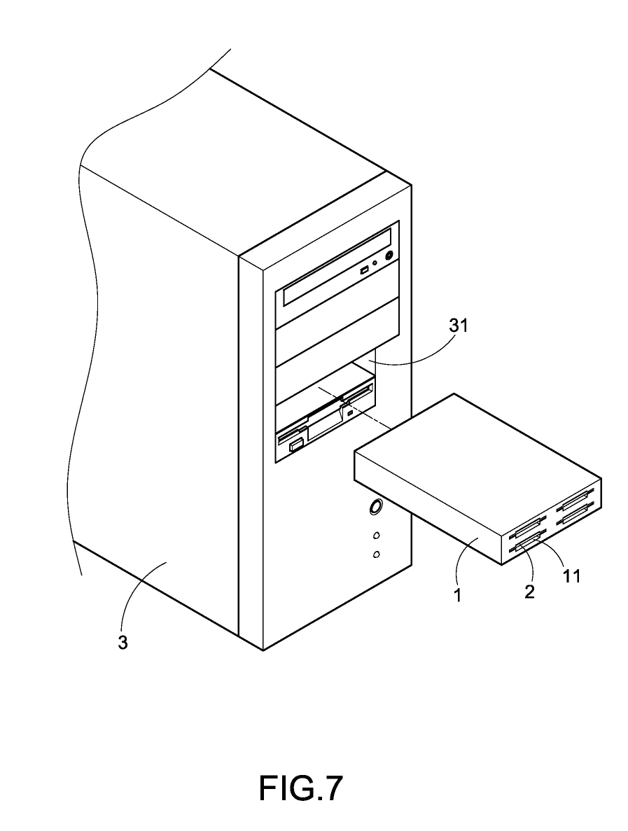

Please refer to FIG. 5 and FIG. 6, which respectively are a perspective structure view and a block illustration according to another embodiment of the present invention. As shown in these figures, the hard disk drive of the present invention mainly includes a device body 1 and a plurality of solid-state memories 2, wherein a plurality of inserting grooves 11 are arranged at the front face of the device body 1 for accommodating certain number of solid-state memory 2, while a connecting seat 12 is arranged at each bottom position of each inserting groove 11 for being electrically connected to the solid-state memory 2; furthermore, a connecting interface 13 is arranged at the rear part of the device body 1 for being electrically connected to the computer mainframe as shown in FIG. 7; in addition, a control unit 14, arranged at the interior of the device body 1, is electrically and respectively connected to each connecting seat 12 and connecting interface 13, such that the connecting unit 14 is electrically connected to the solid-state memory 2 inserted in the inserting groove 11 through the connecting 12 and is formed as a magnetic disk array (RAID) configuration, making the control unit 14 control the solid-state memory 2 connected by the connecting seat 12; on the other hand, at least one solid-state memory 2 (there are three pieces of solid-state memory 2 arranged in this embodiment) is arranged and secured at the interior of the device body 1, making the solid-state hard disk drive have fundamental capacity and the plural solid-state memories 2 be electrically connected to the control unit 14, taken as the real memory body of the magnetic disk array (RAID) configuration.

Please refer to FIG. 7, which is an operational illustration according to another embodiment of the present invention. As shown in this figure, a solid-state hard disk drive of the present invention is accommodated in a hard disk accommodating space 31 of the computer mainframe 3 that is electrically connected to the solid-state hard disk drive through the connecting interface 13, making the data or order to be stored enter the solid-state hard disk drive through the connecting interface 13 and received by the control unit 14 that then re-integrates the data or order to be accessed through the embedded software, finally, the storing or reading task being proceeded in each solid-state memory 2; in addition, if the capacity of the solid-hard disk drive is insufficient, then it is possible to provide another solid-state memory 2 with same specification, which will be inserted into the inserting groove 11 at front face of the device body 1, taken as the real memory body of the magnetic disk array (RAID) configuration, thereby, the accumulated capacity of the solid-state hard disk drive being substantially extended.

Aforementioned description is only preferable embodiment according to the present invention, being not used to limit its executing scope. Any equivalent variation and modification made according to appended claims is all covered by the claims claimed by the present invention.

What is claimed is:

1. A solid-state hard disk drive, simulating a single hard disk drive with a magnetic disk array system, comprising:
a device body, on which a plurality of inserting grooves are arranged, each bottom parts of the plural inserting grooves being arranged a connecting seat separately, another side face of the device body being arranged a connecting interface;
one or more solid-state memory, which is inserted into the inserting groove and is electrically connected to the connecting seat for the provision of a media of data storage;
a control unit, which is arranged at the interior of the device body and is formed as a electrical connection to each connecting seat and the connecting interface for controlling each solid-state memory inserted on the connecting seat for being integrated as a single memory and for controlling its accessing motion;
wherein the capacity needed by the solid-state hard disk drive may be maintained by renewing or increasing the number of the solid-state memory.

2. The solid-state hard disk drive according to claim 1, wherein one or more solid-state memory is arranged at the interior of the device body and is electrically connected the control unit.

3. The solid-state hard disk drive according to claim 1, wherein the specification of the device body is a 3.5 inch hard disk box.

4. The solid-state hard disk drive according to claim 1, wherein the specification of the device body is a 5.25 inch hard disk box.

5. The solid-state hard disk drive according to claim 1, wherein the connecting interface is SATA.

6. The solid-state hard disk drive according to claim 1, wherein the connecting interface is IDE.

7. The solid-state hard disk drive according to claim 1, wherein the connecting interface is a USB interface.

8. The solid-state hard disk drive according to claim 1, wherein the connecting seat is SATA.

9. The solid-state hard disk drive according to claim 1, wherein the connecting seat is IDE.

10. The solid-state hard disk drive according to claim 1, wherein the solid-state memory is a flash memory.
